(19) United States
(12) Patent Application Publication
(10) Pub. No.: US 2021/0020505 A1
(43) Pub. Date: Jan. 21, 2021

(54) METHOD OF MANUFACTURING A SEMICONDUCTOR PACKAGE

(71) Applicant: Samsung Electronics Co., Ltd., Suwon-si (KR)

(72) Inventors: Jaegwon Jang, Hwaseong-si (KR); Seokhyun Lee, Hwaseong-si (KR); Jongyoun Kim, Seoul (KR); Minjun Bae, Yongin-si (KR)

(21) Appl. No.: 16/797,990

(22) Filed: Feb. 21, 2020

(30) Foreign Application Priority Data
Jul. 16, 2019 (KR) 10-2019-0085822

(51) Int. Cl. H01L 21/768; H01L 23/00; H01L 21/56

(52) U.S. Cl. CPC H01L 21/76877; H01L 24/14; H01L 21/565; H01L 21/76802; H01L 24/11

(57) ABSTRACT

A method of manufacturing a semiconductor package is provided including forming a lower redistribution layer. A conductive post is formed on the lower redistribution layer. A semiconductor chip is mounted on the lower redistribution layer. A molding member is formed on the lower redistribution layer. An upper surface of the molding member is at a level lower than an upper surface of the conductive post. An insulating layer is formed on the molding member. An upper surface of the insulating layer is at a level higher than the upper surface of the conductive post. The insulating layer is etched to expose the upper surface of the conductive post. An upper redistribution layer is formed on the insulating layer. The upper redistribution layer is electrically connected to the conductive post.

### CROSS-REFERENCE TO RELATED APPLICATION

This application claims priority under 35 U.S.C. § 119 to Korean Patent Application No. 10-2019-0085822, filed on Jul. 16, 2019, in the Korean Intellectual Property Office, the disclosure of which is incorporated by reference herein in its entirety.

### TECHNICAL FIELD

The present inventive concept relates to a method of manufacturing a semiconductor package.

### DISCUSSION OF THE RELATED ART

Semiconductor devices are being manufactured with increased storage capacity and capabilities that can be quickly driven. A semiconductor package including the semiconductor device with increased storage capacity and capabilities is simultaneously required to be thin and light.

In response to this trend, research into a package-on-package (PoP) type semiconductor package is being conducted. In the PoP-type semiconductor package, the upper semiconductor package is stacked on the lower semiconductor package. For example, research into methods of stably mounting the upper semiconductor package on the lower semiconductor package, and electrically connecting the upper semiconductor package to an external device is of increasing interest.

### SUMMARY

According to an exemplary embodiment of the present inventive concept, a method of manufacturing a semiconductor package is provided including forming a lower redistribution layer. A conductive post is formed on the lower redistribution layer. A semiconductor chip is mounted on the lower redistribution layer. A molding member is formed on the lower redistribution layer. An upper surface of the molding member is at a level lower than an upper surface of the conductive post. An insulating layer is formed on the molding member. An upper surface of the insulating layer is at a level higher than the upper surface of the conductive post. The insulating layer is etched to expose the upper surface of the conductive post. An upper redistribution layer is formed on the insulating layer. The upper redistribution layer is electrically connected to the conductive post.

According to an exemplary embodiment of the present inventive concept, the method of manufacturing the semiconductor package further includes mounting an external connection terminal on the lower redistribution layer. The forming of the upper redistribution layer includes coating a photoresist layer on the insulating layer. An alignment key formed on a photomask is aligned with the upper surface of the conductive post. The photoresist layer is patterned by using the photomask. An upper redistribution pattern and an upper insulating pattern are formed.

According to an exemplary embodiment of the present inventive concept, the forming of the upper redistribution pattern and the upper insulating pattern include forming a plurality of upper redistribution patterns and a plurality of upper insulating patterns. A lowermost portion of the upper redistribution patterns is formed at a level higher than the upper surface of the insulating layer. A lower surface of the lowermost portion of the upper redistribution patterns is formed at the same level as the upper surface of the insulating layer and the upper surface of the conductive post.

According to an exemplary embodiment of the present inventive concept, the forming of the molding member on the lower redistribution layer by forming a first molding member on the lower redistribution layer. The first molding member includes a first filler, The first filler is included in the first molding member at a weight ratio of about 30 wt % to about 90 wt %.

According to an exemplary embodiment of the present inventive concept, the forming of the insulating layer on the molding member includes forming a first insulating layer on the molding member. The first insulating layer includes a second filler. A weight ratio of the second filler in the first insulating layer is less than the weight ratio of the first filler in the first molding member.

According to an exemplary embodiment of the present inventive concept, the second filler in the first insulating layer at a weight ratio of about 0.1 wt % to about 30 wt %.

According to an exemplary embodiment of the present inventive concept, the forming of the insulating layer on the molding member includes forming a first insulating layer on the molding member. The first insulating layer includes polyimide, epoxy, synthetic rubber, and/or benzocyclobutene (BCB).

According to an exemplary embodiment of the present inventive concept, the conductive post is formed having a cylindrical or polygonal shape on the lower redistribution layer.

According to an exemplary embodiment of the present inventive concept, a lower semiconductor package of a package-on-package type semiconductor package includes forming a lower redistribution layer. A conductive post is formed on the lower redistribution layer. A first semiconductor chip is mounted on the lower redistribution layer. A molding member is mounted on the lower redistribution layer. An insulating layer is formed on the molding member. The insulating layer is etched to expose an upper surface of the conductive post. An upper redistribution layer on the insulating layer. The upper redistribution layer is electrically connected to the conductive post. An external connection terminal is mounted on the lower redistribution layer. The package-on-package type semiconductor package includes an upper semiconductor package disposed on the lower semiconductor package.

According to an exemplary embodiment of the present inventive concept, forming the molding member on the lower redistribution layer. An upper surface of the molding member is at a level lower than an upper surface of the conductive post. The forming of the insulating layer on the molding member includes forming the insulating layer on the molding member. An upper surface of the insulating layer is at a level higher than the upper surface of the conductive post.

According to an exemplary embodiment of the present inventive concept, the method of manufacturing the lower semiconductor package includes mounting the first semiconductor chip on the lower redistribution layer by attaching an adhesive layer on the lower redistribution layer and electrically connecting a second connection terminal electrically connected to the first semiconductor chip to the lower redistribution layer.

According to an exemplary embodiment of the present inventive concept, the forming of the upper redistribution layer includes coating a photoresist layer on the insulating layer. An alignment key formed on a photomask is aligned with the upper surface of the conductive post. The photoresist layer is patterned by using the photomask. An upper redistribution pattern and an upper insulating pattern are formed.

According to an exemplary embodiment of the present inventive concept, the forming of the upper redistribution pattern and the upper insulating pattern includes forming a plurality of upper redistribution patterns and a plurality of upper insulating patterns. A lowermost portion of the upper redistribution pattern is formed flat and is not bent toward the conductive post. A portion of the lowermost portion of the upper redistribution pattern is formed to contact the upper surface of the conductive post.

According to an exemplary embodiment of the present inventive concept, the forming of the molding member on the lower redistribution layer includes forming a first molding member on the lower redistribution layer. The first molding member includes a first filler. The first filler is included in the first molding member at a weight ratio of about 30 wt % to about 90 wt %.

According to an exemplary embodiment of the present inventive concept, the forming of the insulating layer on the molding member includes forming a first insulating layer without a filler on the first molding member.

According to an exemplary embodiment of the present inventive concept, a method of manufacturing a semiconductor package includes forming a lower redistribution layer on a support substrate. A conductive post is formed on the lower redistribution layer. A semiconductor chip is mounted on the lower redistribution layer. A molding member is formed on the lower redistribution layer. An upper surface of the molding member is at a level lower than an upper surface of the conductive post. An insulating layer is formed on the molding member. An upper surface of the insulating layer is at a level higher than the upper surface of the conductive post. The insulating layer is etched such that a level of the upper surface of the insulating layer is the same as a level of the upper surface of the conductive post. An upper redistribution layer formed is electrically connected to the conductive post on the insulating layer. The support substrate is separated from the lower redistribution layer. An external connection terminal is mounted on the lower redistribution layer.

According to an exemplary embodiment of the present inventive concept, the forming of the conductive post includes forming the conductive post having a cylindrical or polygonal shape on the lower redistribution layer. The forming of the upper redistribution layer includes coating a photoresist layer on the insulating layer. An alignment key formed on a photomask is aligned with the upper surface of the conductive post. The photoresist layer is patterned by using the photomask. An upper redistribution pattern and an upper insulating pattern are formed.

According to an exemplary embodiment of the present inventive concept, the forming of the upper redistribution pattern and the upper insulating pattern includes forming a plurality of upper redistribution patterns and a plurality of upper insulating patterns. A lowermost portion of the upper redistribution pattern is formed extending in a direction parallel to a direction in which the upper surface of the insulating layer extends. The lowermost portion of the upper redistribution pattern is formed flat and is not bent toward the conductive post. A portion of the lowermost portion of the upper redistribution pattern is formed to contact the upper surface of the conductive post.

According to an exemplary embodiment of the present inventive concept, the forming of the upper redistribution pattern and the upper insulating pattern includes forming a plurality of upper redistribution patterns and a plurality of upper insulating patterns. A lowermost portion of the upper redistribution patterns is formed at a level higher than an upper surface of the insulating layer. The upper surface of the lowermost part of the upper redistribution pattern does not comprise a step. A lower surface of the lowermost portion of the upper redistribution patterns is formed at the same level as the upper surface of the insulating layer and the upper surface of the conductive post.

According to an exemplary embodiment of the present inventive concept, the forming of the molding member on the lower redistribution layer includes forming a first molding member on the lower redistribution layer. The first molding member includes a first filler. The forming of the insulating layer on the molding member includes forming a first insulating layer on the molding member. The first insulating layer includes a second filler. The first filler is included in the first molding member at a weight ratio of about 30 wt % to about 90 wt %, and the second filler is included in the first insulating layer at a weight ratio of about 0.1 wt % to about 30 wt %.

### BRIEF DESCRIPTION OF THE DRAWINGS

The above and other aspects and features of the present inventive concept will become more clearly understood by describing exemplary embodiments thereof in detail with reference to the accompanying drawings in which:

FIGS. 1 to 3 are cross-sectional views illustrating a lower semiconductor package of a package-on-package type semiconductor package according to an exemplary embodiment of the present inventive concept;

FIGS. 4 and 5 are cross-sectional views illustrating a package-on-package type semiconductor package according to an exemplary embodiment of the present inventive concept;

FIG. 6 is a flowchart illustrating steps in a method of manufacturing a lower semiconductor package of a package-on-package type semiconductor package, according to an exemplary embodiment of the present inventive concept;

FIGS. 7 to 22 are diagrams illustrating steps in a method of forming a lower semiconductor package of a package-on-package type semiconductor package, according to an exemplary embodiment of the present inventive concept; and

FIGS. 23 and 24 are diagrams illustrating steps in a method of mounting an upper semiconductor package on a lower semiconductor package, according to an exemplary embodiment of the present inventive concept.

### DETAILED DESCRIPTION OF THE EMBODIMENTS

Hereinafter, example embodiments of the present inventive concept will be described in detail with reference to the accompanying drawings.

Like reference numerals may refer to like elements throughout this application.

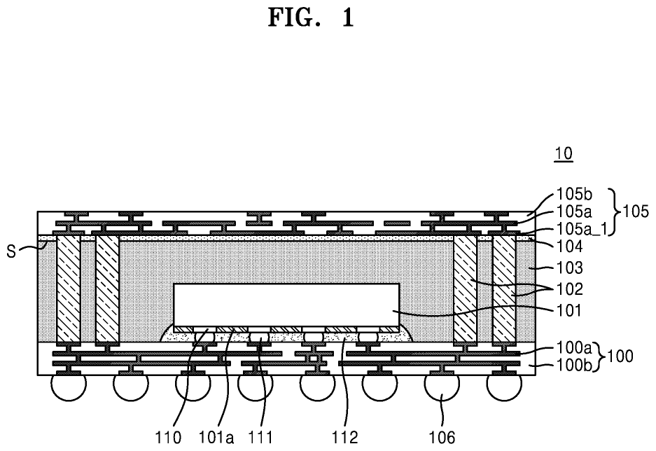

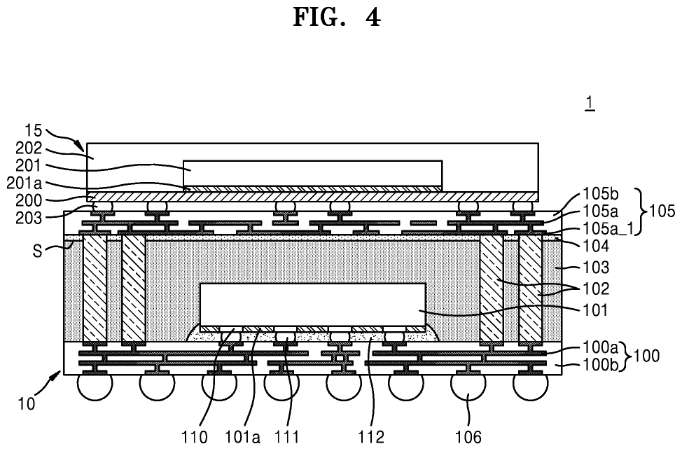

FIG. 1 is a cross-sectional view of a semiconductor package 10 according to an exemplary embodiment of the present inventive. The semiconductor package 10 of FIG. 1 may be a lower semiconductor package 10 of a package-on-package type semiconductor package 1 (shown in FIG. 4).

Referring to FIG. 1, the semiconductor package 10 may include a lower redistribution layer 100, a first semiconductor chip 101, a conductive post 102, a first molding member 103, an insulating layer 104, an upper redistribution layer 105, and an external connection terminal 106.

Referring to FIG. 1, the lower redistribution layer 100 may be under the first semiconductor chip 101 and may support the first semiconductor chip 101. The lower redistribution layer 100 may include a lower redistribution pattern 100a and a lower insulating pattern 100b.

The lower redistribution pattern 100a may be electrically connected to the first semiconductor chip 101. For example, the lower redistribution pattern 100a may be electrically connected to a first pad 110 of the first semiconductor chip 101. In addition, the lower redistribution pattern 100a may be electrically connected to the conductive post 102. The lower redistribution pattern 100a may provide an electrical connection path for electrically connecting the first semiconductor chip 101 and a second semiconductor chip 201 (shown in FIG. 4) to the external connection terminal 106.

The lower insulating pattern 100b may at least partially surround the lower redistribution pattern 100a. The lower insulating pattern 100b may protect the lower redistribution pattern 100a from an external impact and may prevent an electrical short circuit of the lower redistribution pattern 100a. The lower insulating pattern 100b may include silicon oxide, silicon nitride, and/or polymer, but is not limited thereto. For example, the lower insulating pattern 100b may include epoxy or polyimide, but is not limited thereto.

In an exemplary embodiment of the present inventive concept, the first semiconductor chip 101 may be mounted on the lower redistribution layer 100 and electrically connected to the lower redistribution pattern 100a of the lower redistribution layer 100. The first semiconductor chip 101 may include a memory semiconductor device. The memory semiconductor device may include, for example, a volatile memory semiconductor device such as dynamic random access memory (DRAM) or static random access memory (SRAM), and may include a non-volatile memory semiconductor device such as a phase-change random access memory (PRAM), a magneto-resistive random access memory (MRAM), a ferroelectric random access memory (FeRAM), or a resistive random access memory (RRAM).

In addition, the first semiconductor chip 101 may include a logic semiconductor device. The first semiconductor chip 101 may include, for example, a logic semiconductor device such as a central processor unit (CPU), a micro processor unit (MPU), a graphics processor unit (GPU), or an application processor (AP).

In an exemplary embodiment of the present inventive concept, the first semiconductor chip 101 may include a first semiconductor chip insulating layer 101a, a first pad 110, and a first connection terminal 111. The first semiconductor chip insulating layer 101a may be formed below the first semiconductor chip 101. The first semiconductor chip 101 may include a plurality of individual devices of various types. The plurality of individual devices may include various microelectronic devices, for example, a metal-oxide-semiconductor filed effect transistor (MOSFET), a complementary metal-insulator-semiconductor (CMOS), transistors of a system large scale integration (system LSI), an image sensor (such as a CMOS imaging sensor (CIS)), a micro-electro-mechanical systems (MEMS), an active device, a passive device, and the like.

In addition, the first pad 110 may be formed under the first semiconductor chip 101 and may be electrically connected to a plurality of individual devices formed in the first semiconductor chip 101. The first connection terminal 111 may be disposed between the first pad 110 and the lower redistribution layer 100. In addition, the first connection terminal 111 may contact the first pad 110 and the lower redistribution pattern 100a and electrically connect the first pad 110 to the lower redistribution pattern 100a.

In an exemplary embodiment of the present inventive concept, the semiconductor package 10 may further include an adhesive layer 112. The adhesive layer 112 may be disposed between the first semiconductor chip 101 and the lower redistribution layer 100. The adhesive layer 112 may at least partially surround side surfaces of the first connection terminal 111 under the first semiconductor chip 101. In addition, the adhesive layer 112 may at least partially surround at least a portion of the side surfaces of the first semiconductor chip 101. The adhesive layer 112 may include a non-conductive film (NCF), for example, a film of an insulating polymer. The adhesive layer 112 may be configured to firmly attach the first semiconductor chip 101 on the lower redistribution layer 100.

In an exemplary embodiment of the present inventive concept, the conductive post 102 may include a conductive electrode of a pillar shape penetrating the first molding member 103 and the insulating layer 104 on the lower redistribution layer 100. For example, the conductive post 102 may have a pillar shape extending in a direction perpendicular to the plane of an upper surface of the lower redistribution layer 100. In addition, a lower surface of the conductive post 102 may be electrically connected to the lower redistribution pattern 100a of the lower redistribution layer 100, and an upper surface of the conductive post 102 may be electrically connected to an upper redistribution pattern 105a of the upper redistribution layer 105.

The conductive post 102 may be formed outside a side surface of the first semiconductor chip 101 and may at least partially surround the first semiconductor chip 101. In addition, the upper surface of the conductive post 102 may be at a level higher than an upper surface of the first molding member 103. For example, a maximum height of the conductive post 102 relative to the lower redistribution layer 100 may be greater than a maximum height of the first molding member 103 in a thickness direction (e.g., a direction perpendicular to a plane of the lower redistribution layer 100). In addition, the upper surface of the conductive post 102 may be at substantially the same level as an upper surface of the insulating layer 104. For example, the upper surface of the conductive post 102 may be coplanar with the upper surface of the insulating layer 104. For example, the height of the conductive post 102 may be substantially equal to the sum of heights of the first molding member 103 and the insulating layer 104.

The conductive post 102 may be formed on the lower redistribution layer 100 in plural. In addition, the conductive post 102 may have a shape of a circular pillar (e.g., a cylindrical shape) or a shape of a polygonal pillar. For example, the conductive post 102 may have a shape of a triangular pillar, a tetragonal pillar, a pentagonal pillar, a hexagonal pillar, and/or an octagonal pillar.

The conductive post 102 may include a barrier film formed on a surface of the pillar, and a buried conductive layer filling an inside of the barrier film. The buried conductive layer may include a conductive material, for example, a metal of copper (Cu), aluminum (Al), nickel (Ni), tungsten (W), platinum (Pt), and/or gold (Au).

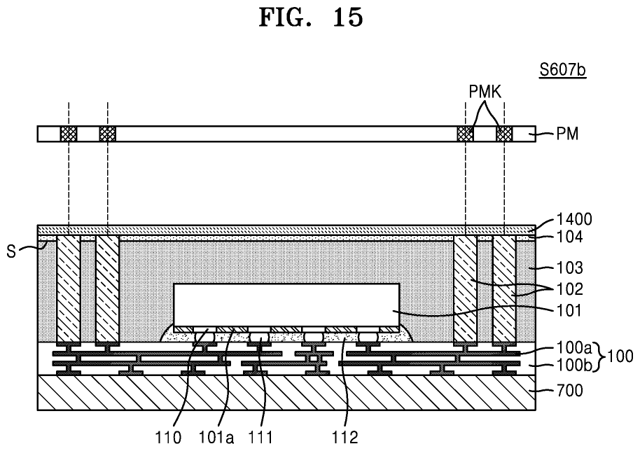

In addition, the conductive post 102 may be used as an alignment key in a step of forming the upper redistribution layer 105. For example, the upper surface of the conductive post 102 may be at substantially the same level as the upper surface of the insulating layer 104, and thus, the upper surface of the conductive post 102 may be easily aligned with an alignment key PMK in a photomask PM (shown in FIG. 15) for forming the upper redistribution layer 105.

In an exemplary embodiment of the present inventive concept, the first molding member 103 may at least partially surround the first semiconductor chip 101 and the conductive post 102 on the lower redistribution layer 100. For example, the first molding member 103 on the lower redistribution layer 100 may at least partially surround side and upper surfaces of the first semiconductor chip 101. In addition, the first molding member 103 may at least partially surround the side surface of the conductive post 102. However, the upper surface of the first molding member 103 may be formed at a level lower than a level of the upper surface of the conductive post 102, and therefore the first molding member 103 might not cover the upper surface of the conductive post 102. For example, an upper surface of the conductive post 102 may protrude in a thickness direction from an upper surface of the first molding member 103. The first molding member 103 may firmly hold the first semiconductor chip 101 and the conductive post 102 on the lower redistribution layer 100.

The first molding member 103 may include an insulating polymer and/or an epoxy resin. For example, the first molding member 103 may include an epoxy molding compound (EMC).

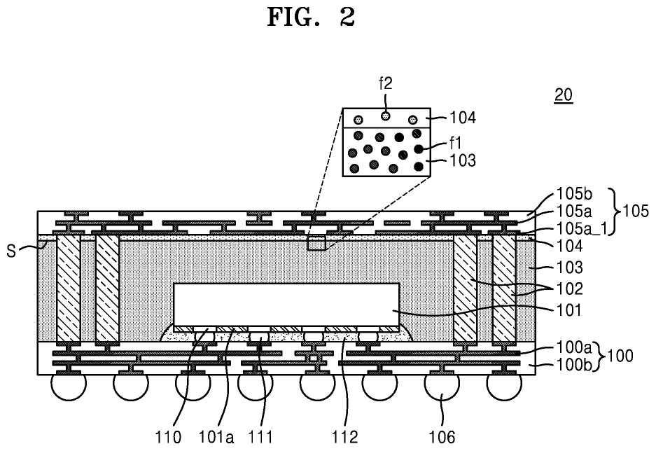

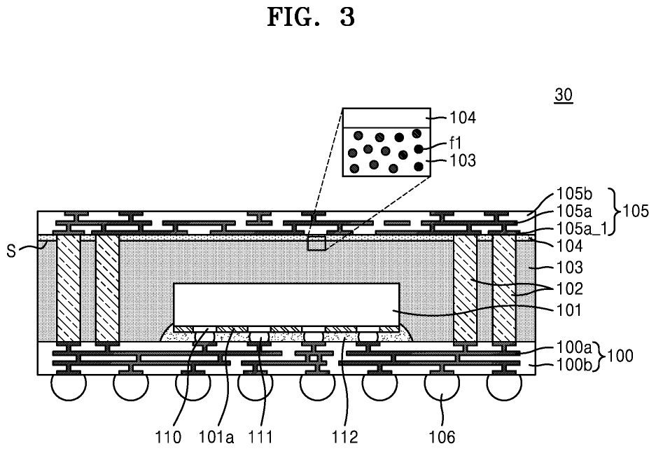

In addition, the first molding member 103 may include a first filler f1 therein, as shown in FIG. 2. The first filler f1 may be included in the first molding member 103 at a weight ratio of about 30 wt % to about 90 wt %. Since the first molding member 103 may include the first filler f1, the risk of breakage of the semiconductor package 10 due to external impact may be reduced. In addition, since the first molding member 103 may include the first filler ft, the risk of breakage of the semiconductor package 10 due to heat may be reduced. The first filler f1 in the first molding member 103 will be described in more detail with reference to FIGS. 2 and 3.

In an exemplary embodiment of the present inventive concept, the insulating layer 104 may at least partially surround a portion of an upper portion of the conductive post 102 on the first molding member 103. In addition, the upper surface of the insulating layer 104 may be at substantially the same level as the upper surface of the conductive post 102, and thus the insulating layer 104 might not cover the upper surface of the conductive post 102. An interface S between a lower surface of the insulating layer 104 and the upper surface of the first molding member 103 may be at a level lower than the upper surface of the conductive post 102. For example, the interface S may be at a certain position toward the lower redistribution layer 100 below a level of the upper surface of the conductive post 102.

The insulating layer 104 may include an insulating material. For example, the insulating layer 104 may include an insulating material of polyimide, epoxy, synthetic rubber, and/or benzocyclobutene. In addition, the insulating layer 104 may include a photosensitive film, but is not limited thereto, and may also include a non-photosensitive film.

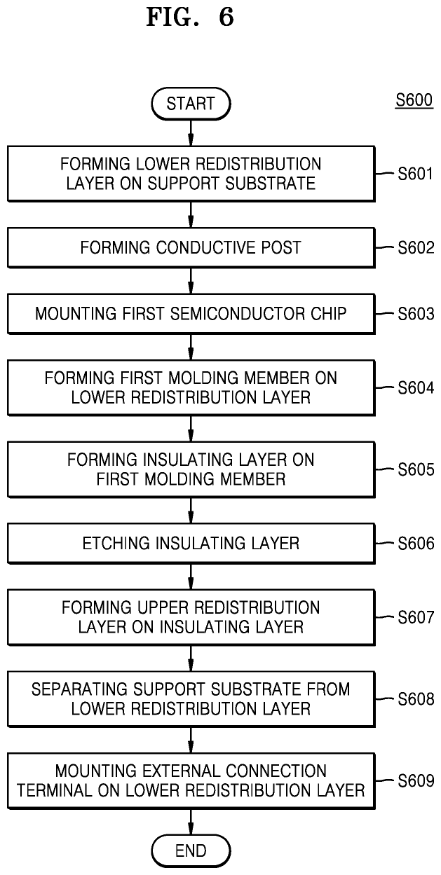

In addition, the insulating layer 104 may include a second filler f2 therein, as shown in FIG. 2. The weight ratio of the second filler f2 in the insulating layer 104 may be less than the weight ratio of the first filler f1 in the first molding member 103. For example, the second filler f2 may be included in the insulating layer 104 at a weight ratio of about 0.1 wt % to about 30 wt %. However, the present inventive concept is not limited thereto, and the insulating layer 104 might not include the second filler f2. The weight ratio of the second filler f2 in the insulating layer 104 may be less than the weight ratio of the first filler f1 in the first molding member 103, and thus, the inclination of the conductive post 102 may be prevented in step S606 of etching the insulating layer 104 as described with reference to FIG. 6. The second filler 2 in the insulating layer 104 will be described in more detail with reference to FIGS. 2 and 3.

In an exemplary embodiment of the present inventive concept, the upper redistribution layer 105 may be on the insulating layer 104 and may support the second semiconductor chip 201 (shown in FIG. 4) to be described later. The upper redistribution layer 105 may include an upper redistribution pattern 105a and an upper insulating pattern 105b.

The upper redistribution pattern 105a may be electrically connected to the conductive post 102 and the second semiconductor chip 201 in FIG. 4. For example, the upper redistribution pattern 105a may be electrically connected to the conductive post 102 and a second connection terminal 203 of the upper semiconductor package 15. The upper redistribution pattern 105a may provide an electrical connection path for electrically connecting the second semiconductor chip 201 to the conductive post 102.

The upper insulating pattern 105b may at least partially surround the upper redistribution pattern 105a. The upper insulating pattern 105b may protect the upper redistribution pattern 105a from an external impact and may prevent an electrical short circuit of the upper redistribution pattern 105a. The upper insulating pattern 105b may include silicon oxide, silicon nitride, and/or polymer, but is not limited thereto. For example, the upper insulating pattern 105b may include epoxy or polyimide, but is not limited thereto.

The upper redistribution pattern 105a may include a lowermost upper redistribution pattern 105a_1. The lowermost upper redistribution pattern 105a_1 may be a redistribution pattern positioned at the lowermost portion of the upper redistribution pattern 105a having a stacked structure. In addition, the lowermost upper redistribution pattern 105a_1 may include a redistribution pattern formed first in the forming of the upper redistribution layer 105.

A lower surface of the lowermost upper redistribution pattern 105a_1 may be at substantially the same level as the upper surface of the insulating layer 104 and the upper surface of the conductive post 102. The lowermost upper redistribution pattern 105a_1 may be formed to extend in a direction parallel to a direction in which the upper surface of the insulating layer 104 extends. In addition, referring to FIG. 1, a shape of the lowermost upper redistribution pattern 105a_1 might not be bent toward the conductive post 102. For example, the lowermost upper redistribution pattern 105a_1 may be flat and might not be inclined toward the conductive post 102. An upper surface of the lowermost upper redistribution pattern 105a_1 might not include a step, and the lowermost upper redistribution pattern 105a_1 may flatly contact the upper surface of the conductive post 102.

FIGS. 2 and 3 are cross-sectional views of semiconductor packages 20 and 30 according to exemplary embodiments of the present inventive concept. For example, the semiconductor packages 20 and 30 of FIGS. 2 and 3 may be the lower semiconductor package 10 of a package-on-package type semiconductor package 1 of FIG. 4.

Referring to FIGS. 2 and 3, the first molding member 103 may include a first filler f1. The first filler f1 may include a material of silica and/or alumina. The first filler f1 may have a size of about 0.1 micrometers to about 30 micrometers or less. The first filler f1 may be included in the first molding member 103 at a weight ratio of about 30 wt % to about 90 wt %. Since the first molding member 103 may include the first filler f1 therein, the risk of breakage of the semiconductor package 10 due to an external impact may be reduced. In addition, since the first molding member 103 may include the first filler f1 therein, the risk of breakage of the semiconductor package 10 due to heat may be reduced.

Referring to FIG. 2, the insulating layer 104 may include a second filler f2. The second filler 2 may include a material of silica and/or alumina. The second filler f2 may have a size of about 0.1 micrometers to about 30 micrometers or less. The weight ratio of the second filler f2 in the insulating layer 104 may be less than the weight ratio of the first filler f1 in the first molding member 103. For example, the second filler f2 may be included in the insulating layer 104 at a weight ratio of about 0.1 wt % to about 30 wt %.

However, the present inventive concept is not limited thereto, and the insulating layer 104 might not include the second filler f2, as shown in FIG. 3. The weight ratio of the second filler f2 in the insulating layer 104 may be less than the weight ratio of the first filler f1 in the first molding member 103, and thus, the inclination of the conductive post 102 may be prevented in step S606 (shown in FIG. 6) of etching the insulating layer 104. In addition, as the inclination of the conductive post 102 may be prevented, the alignment of the photomask PM in FIG. 15 for forming the upper redistribution layer 105 may be easy. For example, the upper surface of the conductive post 102 may be used as an alignment key, and the upper surface of the conductive post 102 may be easily aligned with the alignment key PMK of the photomask PM.

FIG. 4 is a cross-sectional view of a semiconductor package 1 according to an exemplary embodiment of the present inventive concept. For example, the semiconductor package 1 of FIG. 4 may be a package-on-package type semiconductor package including the lower semiconductor package 10 and the upper semiconductor package 15.

In an exemplary embodiment of the present inventive concept, the lower semiconductor package 10 may include the lower redistribution layer 100, the first semiconductor chip 101, the conductive post 102, the first molding member 103, the insulating layer 104, the upper redistribution layer 105, and the external connection terminal 106. Referring to FIG. 4, the upper semiconductor package 15 may be mounted on the lower semiconductor package 10. For example, the upper semiconductor package 15 may be mounted on the upper redistribution layer 105 of the lower semiconductor package 10, and the second semiconductor chip 201 of the upper semiconductor package 15 may be electrically connected to the upper redistribution pattern 105a of the upper redistribution layer 105. In addition, an outer side surface of the upper semiconductor package 15 may be laterally nearer to a center line of the package-on-package type semiconductor package 1 than an outer side surface of the lower semiconductor package 10. For example, the upper semiconductor package 15 may have a smaller width in a cross-sectional view than a width of the semiconductor package 10.

The upper semiconductor package 15 may include a substrate 200, a second semiconductor chip insulating layer 201a, a second semiconductor chip 201, a second molding member 202, and a second connection terminal 203. In an exemplary embodiment of the present inventive concept, the substrate 200 may support the second semiconductor chip 201 and may be electrically connected to the second semiconductor chip 201. The substrate 200 may include a carrier substrate, a printed circuit board (PCB), and/or a wafer on which a redistribution layer is formed.

In an exemplary embodiment of the present inventive concept, the second semiconductor chip 201 may be mounted on the substrate 200 by using the second semiconductor chip insulating layer 201a. For example, the second semiconductor chip insulating layer 201a may include an adhesive material. The second semiconductor chip 201 may be electrically connected to the substrate 200 via a bonding wire or a conductive pad. For example, the second semiconductor chip 201 may be electrically connected to the lower redistribution layer 100 via the substrate 200, the second connection terminal 203, the upper redistribution layer 105, and the conductive post 102.

A width of the second semiconductor chip 201 may be less than a width of the upper redistribution layer 105. However, the present inventive concept is not limited thereto, and the width of the second semiconductor chip 201 may be substantially the same as the width of the upper redistribution layer 105. In addition, the width of the second semiconductor chip 201 may be greater than the width of the first semiconductor chip 101. In an exemplary embodiment of the present inventive concept, the second molding member 202 may be configured to fix the second semiconductor chip 201 on the substrate 200. In addition, the second molding member 202 may at least partially surround the second semiconductor chip 201 on the substrate 200. For example, the second molding member 202 may at least partially surround side and upper surfaces of the second semiconductor chip 201 on the substrate 200. However, the present inventive concept is not limited thereto, and the second molding member 202 may surround only the side surface of the second semiconductor chip 201 on the substrate 200 and might not surround the upper surface thereof.

The second molding member 202 may include a material including an insulating polymer and/or an epoxy resin. For example, the second molding member 202 may include an epoxy molding compound.

In an exemplary embodiment of the present inventive concept, the second connection terminal 203 may be disposed between the substrate 200 and the upper redistribution layer 105.

In addition, the second connection terminal 203 may be electrically connected to the substrate 200 and the upper redistribution layer 105.

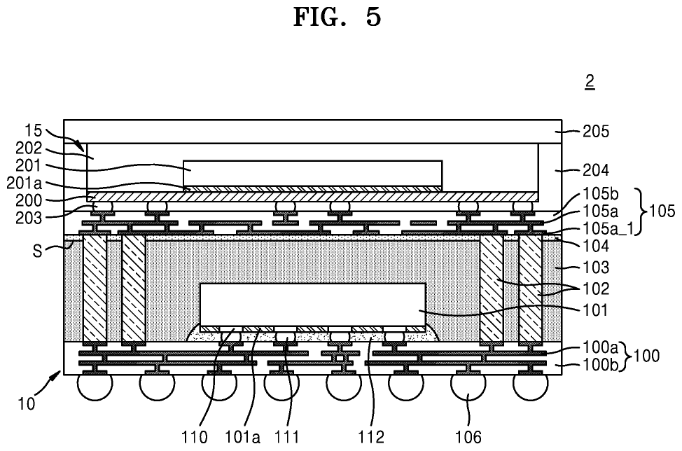

FIG. 5 is a cross-sectional view of a semiconductor package 2 according to an exemplary embodiment of the present inventive concept. For example, the semiconductor package 2 of FIG. 5 may be a package-on-package type semiconductor package including the lower semiconductor package 10 and the upper semiconductor package 15.

The inventive concept regarding the lower semiconductor package 10 and the upper semiconductor package 15 may include the inventive concept described with reference to FIGS. 1 to 4, and thus, detailed descriptions thereof will be omitted.

Referring to FIG. 5, the upper semiconductor package 15 may further include a third molding member 204 and a heat sink 205. In an exemplary embodiment of the present inventive concept, the third molding member 204 may at least partially surround a side surface of the upper semiconductor package 15. In addition, a side surface of the third molding member 204 may be self-aligned with a side surface of the semiconductor package 2.

In an exemplary embodiment of the present inventive concept, a heat sink 205 may be mounted on the third molding member 204. The heat sink 205 may release heat generated in the semiconductor package 2 to the outside. The heat sink 205 may include a metal material having excellent thermal conductivity. For example, the heat sink 205 may include a metal material such as aluminum (Al), nickel (Ni), copper (Cu), magnesium (Mg), and/or silver (Ag).

The heat sink 205 may be attached onto the third molding member 204 by an adhesive film. The adhesive film may include a film having adhesive properties by itself. For example, the adhesive film may include a double-sided adhesive film.

As shown in FIG. 5, the third molding member 204 may cover the side surface of the second molding member 202 but might not cover the upper surface of the second molding member 202. However, the inventive concept is not limited thereto, and the third molding member 204 may cover both the upper and side surfaces of the second molding member 202.

Since the semiconductor package 2 may include the third molding member 204, the structural stability of the semiconductor package 2 may be increased. Accordingly, the semiconductor package 2 may have a low risk of damage from an external impact. In addition, the semiconductor package 2 may include the heat sink 205 to provide excellent heat dissipation performance.

Hereinafter, a method of manufacturing a semiconductor package according to an exemplary embodiment of the present inventive concept will be described in detail with reference to FIGS. 6 to 23. The method of manufacturing the semiconductor package may be a method of manufacturing a package-on-package type semiconductor package including a lower semiconductor package and an upper semiconductor package. The method of manufacturing the package-on-package type semiconductor package may include forming the lower semiconductor package and mounting the upper semiconductor package on the lower semiconductor package.

FIG. 6 is a flowchart of the method of manufacturing the semiconductor package, according to an exemplary embodiment of the present inventive concept. For example, FIG. 6 may be a flowchart illustrating steps S600 of forming the lower semiconductor package 10 in FIG. 1 in the package-on-package type semiconductor package.

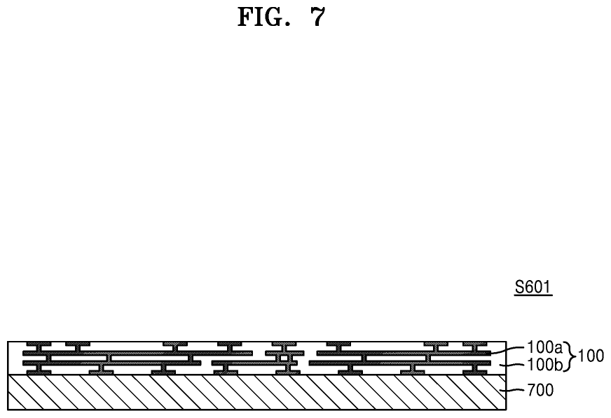

Referring to FIGS. 1 and 6 together, steps S600 of forming the lower semiconductor package may include forming the lower redistribution layer 100 on a support substrate 700 in FIG. 7 (S601), forming the conductive post 102 (S602), mounting the first semiconductor chip 101 (S603), forming the first molding member 103 on the lower redistribution layer 100 (S604), forming the insulating layer 104 on the first molding member 103 (S605), etching the insulating layer 104 (S606), forming the upper redistribution layer 105 on the insulating layer 104 (S607), separating the support substrate 700 from the lower redistribution layer 100 (S608), and mounting the external connection terminal 106 on the lower redistribution layer 100 (S609).

FIGS. 7 to 22 illustrate steps of forming the lower semiconductor package 10. For example, FIG. 7 is a diagram illustrating step S601 of forming the lower redistribution layer 100 on the first support substrate 700.

Referring to FIG. 7, steps S600 of forming the lower semiconductor package may include step S601 of forming the lower redistribution layer 100 on the first support substrate 700. The first support substrate 700 may include a carrier substrate and/or a glass substrate, but the present inventive concept is not limited thereto. Step S601 of forming the lower redistribution layer 100 may include forming the lower redistribution pattern 100a and the lower insulating pattern 100b on the first support substrate 700. The lower redistribution pattern 100a and the lower insulating pattern 100b may be formed by a photolithography process, an electroplating process, and the like.

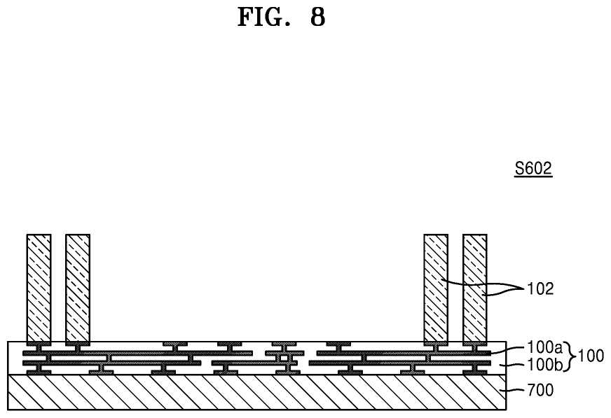

FIG. 8 is a diagram illustrating step S602 of forming the conductive post 102. Referring to FIG. 8, steps S600 of forming the lower semiconductor package 10 may include step 602 of forming the conductive post 102. Step S602 of forming the conductive post 102 may include mounting the conductive post 102 of a pillar shape on the lower redistribution layer 100. For example, the conductive post 102 may be mounted on the lower redistribution layer 100 to extend in a direction perpendicular to the extending direction of the upper surface of the lower redistribution layer 100. The conductive post 102 may be mounted on the lower redistribution layer 100 in the shape of a circular pillar, a triangular pillar, a square pillar, a pentagonal pillar, a hexagonal pillar, and/or an octagonal pillar. In addition, the conductive post 102 may be mounted on the lower redistribution layer 100 to contact the lower redistribution pattern 100a.

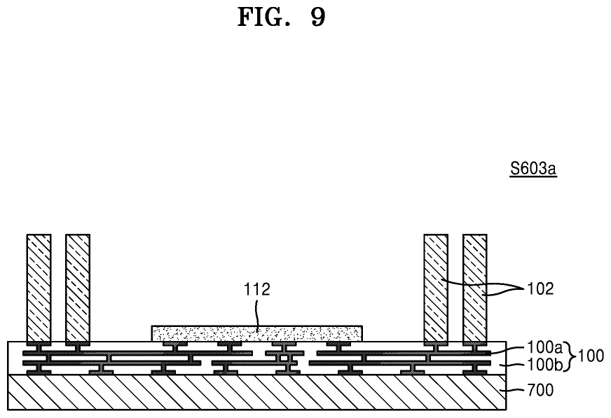

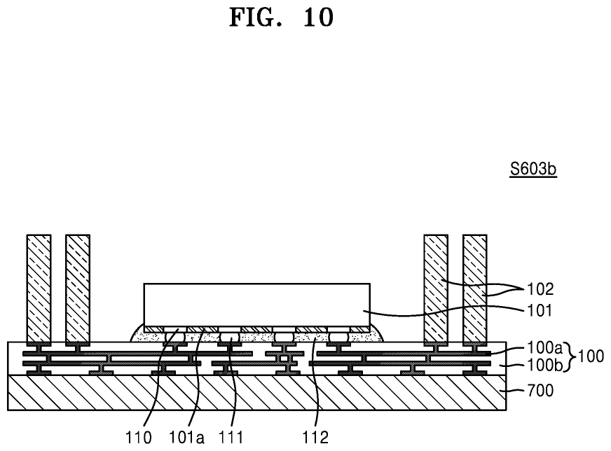

FIGS. 9 and 10 are diagrams illustrating step S603 of mounting a first semiconductor chip 101. Referring to FIGS. 9 and 10, steps S600 of forming the lower semiconductor package may include step S603 of mounting the first semiconductor chip 101. Step S603 of mounting the first semiconductor chip 101 may include step S603a of attaching the adhesive layer 112 and step S603b of electrically connecting the first semiconductor chip 101 to the lower redistribution layer 100.

Referring to FIG. 9, step S603a of attaching the adhesive layer 112 may include attaching a nonconductive adhesive material on the lower redistribution layer 100. The adhesive layer 112 may include a nonconductive film, for example a film including an insulating polymer.

Referring to FIG. 10, step S603b of electrically connecting the first semiconductor chip 101 to the lower redistribution layer 100 may include a step of electrically connecting the first connection terminal 111 of the first semiconductor chip 101 to the lower redistribution pattern 100a of the lower redistribution layer 100. The first semiconductor chip 101 may be mounted on the lower redistribution layer 100 to be surrounded by the conductive post 102.

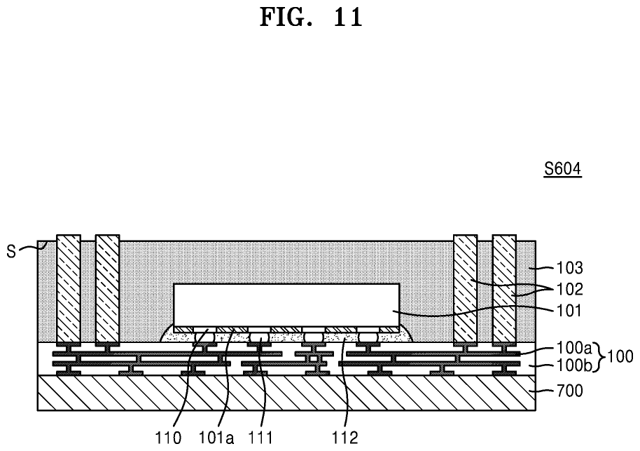

FIG. 11 is a diagram illustrating step S604 of forming the first molding member 103 on the lower redistribution layer 100. Referring to FIG. 11, steps S600 of forming the lower semiconductor package 10 may include step S604 of forming the first molding member 103 on the lower redistribution layer 100 to be formed at a level lower than the upper surface of the conductive post 102.

In an exemplary embodiment of the present inventive concept, step S604 of forming the first molding member 103 on the lower redistribution layer 100 may include a step of forming the first molding member 103 on the lower redistribution layer 100, the first molding member 103 including the first filler f1. For example, the first filler f1 may be included in the first molding member 103 at a weight ratio of about 30 wt % to about 90 wt %.

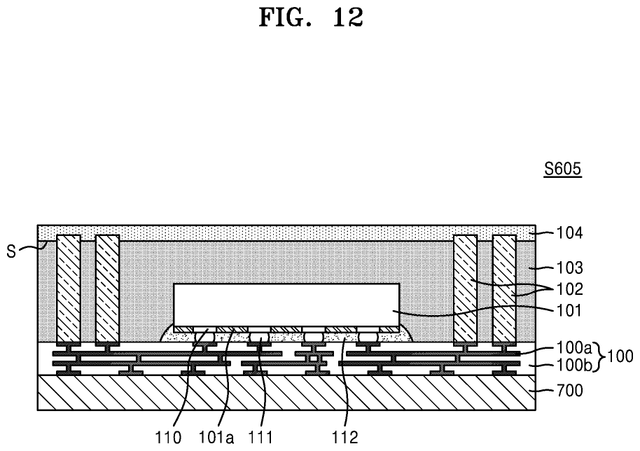

FIG. 12 is a diagram illustrating step S605 of forming the insulating layer 104 on the first molding member 103. Referring to FIG. 12, steps S600 of forming the lower semiconductor package 10 may include step S605 of forming the insulating layer 104 on the first molding member 103 to be formed at a level higher than the upper surface of the conductive post 102.

Step S605 of forming the insulating layer 104 on the first molding member 103 may include a step of forming the insulating layer 104 on the first molding member 103, the insulating layer 104 including polyimide, epoxy, synthetic rubber, and/o benzocyclobutene (BCB).

In an exemplary embodiment of the present inventive concept, step S605 of forming the insulating layer 104 on the first molding member 103 may include a step of forming the insulating layer 104 on the first molding member 103, the insulating layer 104 including the second filler f2. In addition, the weight ratio of the second filler f2 in the insulating layer 104 may be less than the weight ratio of the first filler f1 in the first molding member 103. For example, the second filler f2 may be included in the insulating layer 104 at a weight ratio of about 0.1 wt % to about 30 wt %. However, the inventive concept is not limited thereto, and the insulating layer 104 might not include the second filler f2.

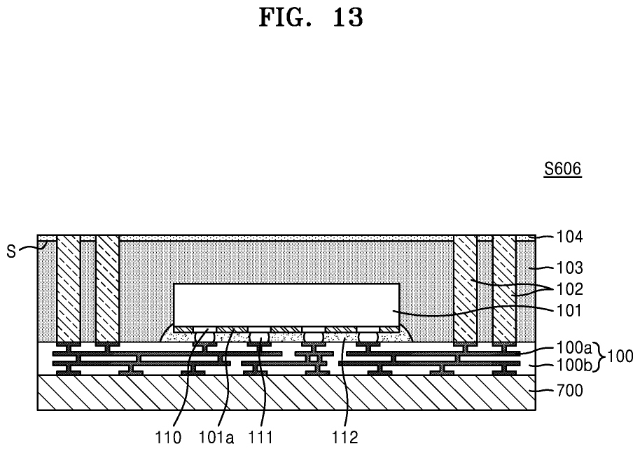

FIG. 13 is a diagram illustrating step S606 of etching the insulating layer 104. Referring to FIG. 13, steps S600 of forming the lower semiconductor package may include a step of etching the insulating layer 104 such that the upper surface of the conductive post 102 is exposed to the outside. For example, step of etching of the insulating layer 104 may include a step S606 of etching the insulating layer 104 such that levels of the upper surface of the insulating layer 104 and the upper surface of the conductive post 102 are substantially the same.

In an exemplary embodiment of the present inventive concept, the insulating layer 104 may be etched by a chemical mechanical polishing (CMP) process and/or an etch-back process but is not limited thereto. In addition, step S606 of etching the insulating layer 104 may include a step of exposing the upper surface of the conductive post 102 to the outside. The exposed upper surface of the conductive post 102 may be used as an alignment key for the alignment with the photomask PM in step S607 of forming the upper redistribution layer 105 to be described later.

A method of manufacturing a semiconductor package, according to a comparative example, may include forming the first molding member 103 including a first filler f1 to be formed at a level higher than the upper surface of the conductive post 102 and etching the first molding member 103 such that a level of the upper surface of the first molding member 103 is substantially the same as a level of the upper surface of the conductive post 102. In the method of manufacturing the semiconductor package, according to the comparative example, the first filler f1 may be separated from the first molding member 103 in a step of etching the first molding member 103. Due to this reason, the conductive post 102 may be inclined toward a region where the first filler f1 is relatively largely separated from the first molding member 103.

In an exemplary embodiment of the present inventive concept, step of forming the lower semiconductor package may include a step S606 of etching the insulating layer 104 such that the level of the upper surface of the insulating layer 104 and the upper surface of the conductive post 102 are substantially the same, wherein the weight ratio of the second filler f2 in the insulating layer 104 may be less than the weight ratio of the first filler f2 in the first molding member 103. The amount of the second filler f2 separated from the insulating layer 104 in the etching of the insulating layer 104 may be less than the amount of the first filler f1 separated from the first molding member 103 in the etching of the first molding member 103 of the comparative example. Accordingly, in step S606 of etching the insulating layer 104, the inclination of the conductive post 102 may be prevented. As the inclination of the conductive post 102 may be prevented, the alignment between the photomask PM and the conductive post 102 may be easily performed in step S607 of forming the upper redistribution layer 105 to be described later.

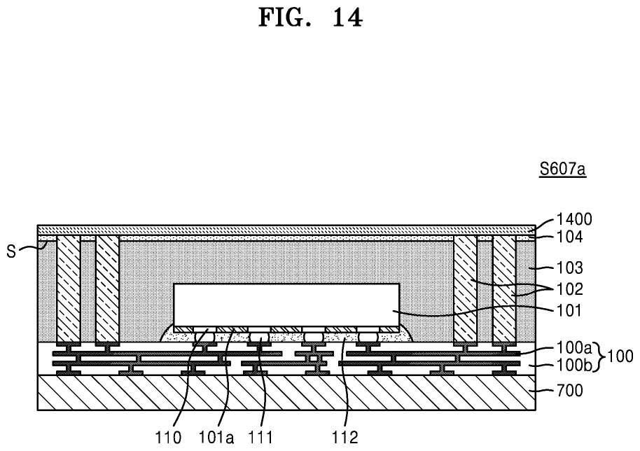

FIGS. 14 to 22 are diagrams illustrating step S607 of forming the upper redistribution layer 105 on the insulating layer 104. Step S607 of forming the upper redistribution layer 105 on the insulating layer 104 may include a step of forming the upper redistribution layer 105 electrically connected to the conductive post 102 on the insulating layer 104.

In an exemplary embodiment of the present inventive concept, step S607 of forming the upper redistribution layer 105 on the insulating layer 104 may include forming a photoresist layer 1400 on the insulating layer 104 (S607a), aligning the alignment key PMK of the photomask PM with the upper surface of the conductive post 102 (S607b), patterning the photoresist layer 1400 using the photomask PM (S607c), and forming the upper redistribution pattern 105a and the upper insulating pattern 105b (S607d_1 to S607d_3).

FIG. 14 is a diagram illustrating step S607a of forming the photoresist layer 1400 on the insulating layer 104. Referring to FIG. 14, the photoresist layer 1400 may be coated on the insulating layer 104. For example, the photoresist layer 1400 may be coated on the insulating layer 104 by a spin coating process. In addition, the photoresist layer 1400 may include a photosensitive polymer that reacts to light.

FIG. 15 is a diagram illustrating step S607b of aligning the alignment key PMK of the photomask PM with the upper surface of the conductive post 102. Referring to FIG. 15, the photomask PM for patterning the photoresist layer 1400 may be provided over the photoresist layer 1400. The photomask PM may include the alignment key PMK, and the alignment key PMK may be a key provided for the alignment with the lower semiconductor package 10. In addition, the alignment key PMK of the photomask PM may be aligned with the upper surface of the conductive post 102. Since the conductive post 102 may include a metal material and the photoresist layer 1400 may include a photosensitive polymer, an alignment apparatus for aligning the upper surface of the conductive post 102 with the alignment key PMK of the photomask PM may observe the upper surface of the conductive post 102 over the photoresist layer 1400.

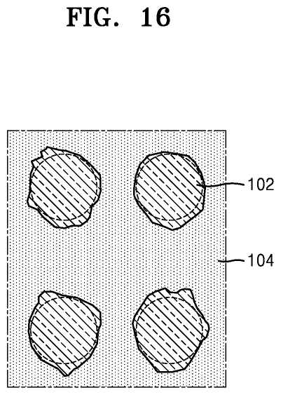

FIG. 16 is a diagram illustrating the alignment of the alignment key PMK of the photomask PM and the upper surface of the conductive post 102, according to a comparative example. As described above, the method of manufacturing the semiconductor package according to the comparative example, may include forming the first molding member 103 including the first filler f1 formed at the level higher than the upper surface of the conductive post 102 and etching the first molding member 103 such that the level of the upper surface of the first molding member 103 is substantially the same as the level of the upper surface of the conductive post 102. In the method of manufacturing the semiconductor package according to the comparative example, the first filler f1 may be separated from the first molding member 103 in a step of etching the first molding member 103, so that the conductive post 102 may be inclined in the first molding member 103 toward the region where the filler f1 is relatively largely separated. In the method of manufacturing the semiconductor package according to the comparative example, the conductive post 102 may be inclined, so that the alignment of the alignment key PMK of the photomask PM with the upper surface of the conductive post 102 may be difficult.

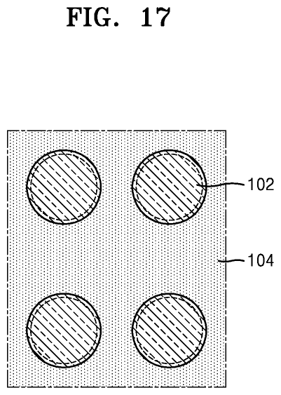

FIG. 17 is a diagram illustrating the alignment of the alignment key PMK of the photomask PM and the upper surface of the conductive post 102 according to an exemplary embodiment of the present inventive concept. The step of forming the lower semiconductor package may include step S606 of etching the insulating layer 104 such that the level of the upper surface of the insulating layer 104 and the upper surface of the conductive post 102 are substantially the same, wherein the weight ratio of the second filler f1 in the insulating layer 104 may be less than the weight ratio of the first filler f1 in the first molding member 103. Accordingly, in a step of etching the insulating layer 104, the amount of the second fillers 2 separated from the insulating layer 104 may be small, and thus the inclination of the conductive post 102 may be prevented. Since the inclination of the conductive post 102 may be prevented, the alignment of the alignment key PMK of the photomask PM with the upper surface of the conductive post 102 may be facilitated.

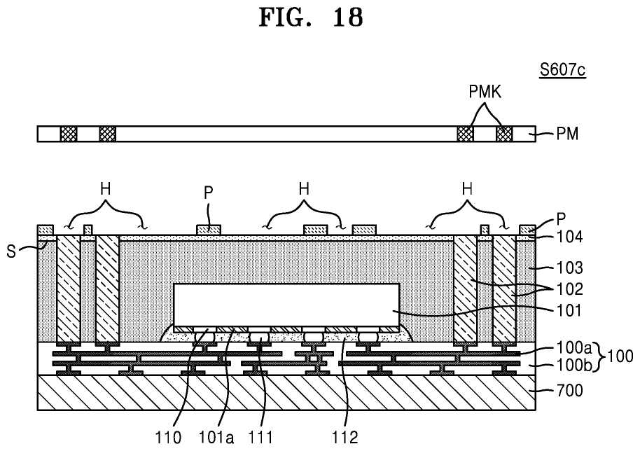

FIG. 18 is a diagram illustrating step S607c of patterning the photoresist layer 1400 by using the photomask PM. Referring to FIG. 18, the photoresist layer 1400 may be patterned by using the photomask PM. For example, step S607c of patterning the photoresist layer 1400 by using the photomask PM may include a step of forming a mask pattern P including an opening H on the insulating layer 104 by an exposure process and a development process.

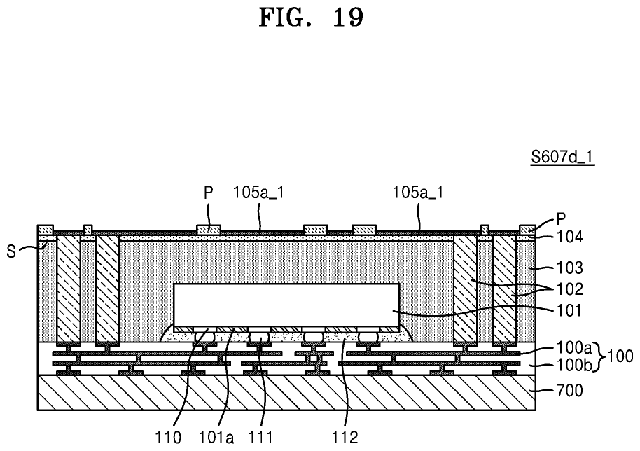

FIGS. 19 to 21 are diagrams illustrating step S607d of forming the upper redistribution pattern 105a and the upper insulating pattern 105b. Referring to FIG. 19, step S607d_1 of forming the upper redistribution pattern 105a may include a step of forming the upper redistribution pattern 105a by filling a conductive material in the opening H in the mask pattern P by an electroplating process. For example, the conductive material may fill portions of the opening H disposed between adjacent portions of the mask pattern P.

In an exemplary embodiment of the present inventive concept, a redistribution pattern located at a lowermost portion of the upper redistribution pattern 105a may be defined as the lowermost upper redistribution pattern 105a_1. The lowermost upper redistribution pattern 105a_1 may have an upper surface that is lower than an upper surface of the mask pattern P. In addition, the lowermost upper redistribution pattern 105a1 may include a redistribution pattern formed first in the forming of the upper redistribution patterns 105a. A portion of the lowermost upper redistribution pattern 105a_1 may contact the upper surface of the conductive post 102. The lowermost upper redistribution pattern 105a_1 may be formed at a level higher than the upper surface of the insulating layer 104, and the lowermost upper redistribution pattern 105a_1 may be at substantially the same level as the upper surface of the insulating layer 104 and the upper surface of the conductive post 102. The lowermost upper redistribution pattern 105a_1 may be formed to extend in the direction parallel to the direction in which the upper surface of the insulating layer 104 extends. In addition, the shape of the lowermost upper redistribution pattern 105a_1 might not be bent toward the conductive post 102. For example, the lowermost upper redistribution pattern 105a_1 may be flat without being inclined toward the conductive post 102. The upper surface of the lowermost upper redistribution pattern 105a_1 might not include a step, and the lowermost upper redistribution pattern 105a_1 may flatly contact the upper surface of the conductive post 102.

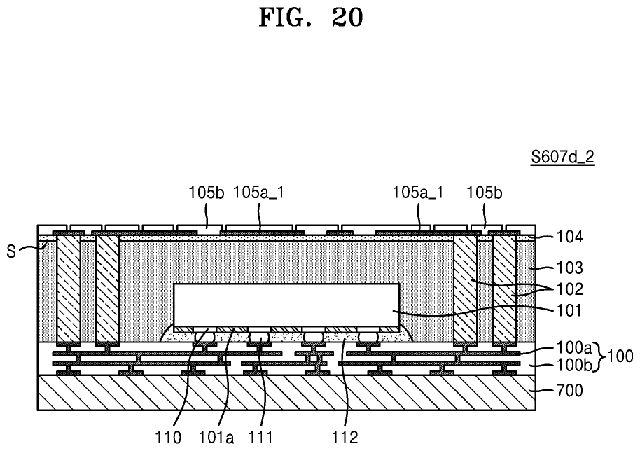

Referring to FIG. 20, the mask pattern P on the insulating layer 104 may be removed. For example, the mask pattern P may be removed by an ashing and strip process. Step S607d_2 of forming the upper insulating pattern 105b may include a step of coating an insulating material layer on the lowermost upper redistribution pattern 105a_1 and a step of patterning the coated insulating material layer by an exposure process and a developing process to form the upper insulating pattern 105b.

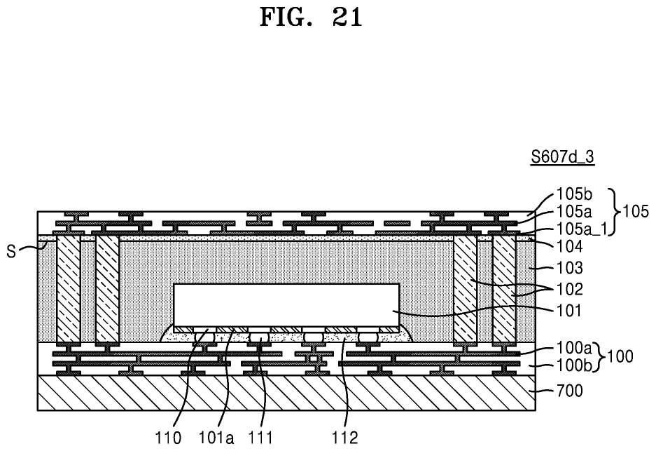

Referring to FIG. 21, step S607d of forming the upper redistribution pattern 105a and the upper insulating pattern 105b may include step S607d_3 of forming a plurality of the upper redistribution patterns 105a and a plurality of the upper insulating patterns 105b by stacking thereof.

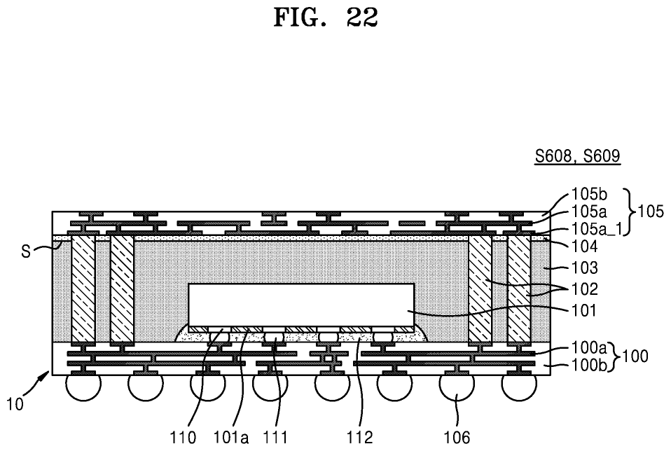

FIG. 22 is a diagram illustrating step S608 of separating the first support substrate 700 from the lower redistribution layer 100 and step S609 of mounting the external connection terminal 106 on the lower redistribution layer 100. Referring to FIG. 22, the first support substrate 700 may be separated from the lower redistribution layer. In addition, the external connection terminal 106 may be mounted on the lower redistribution layer 100 to be electrically connected to the lower redistribution pattern 100a. The external connection terminal 106 may include a metal material including tin, silver, copper, and/or aluminum.

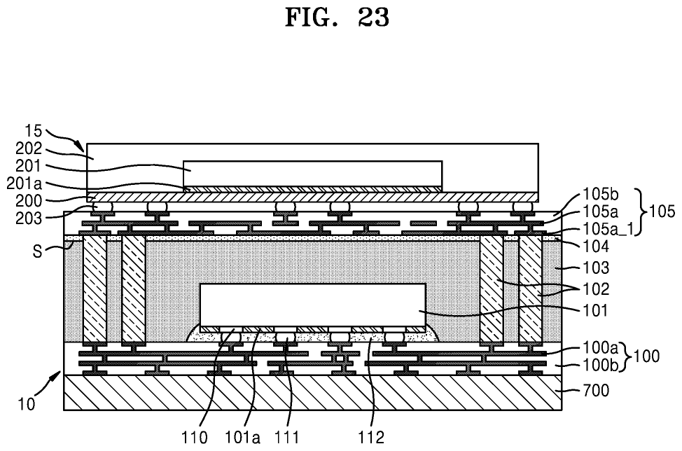

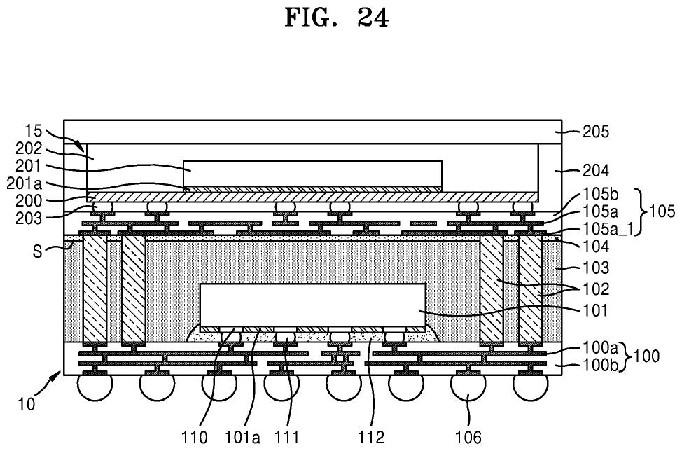

FIGS. 23 and 24 are diagrams illustrating steps in a method of mounting the upper semiconductor package 15 on the lower semiconductor package 10 according to an exemplary embodiment of the present inventive concept. Since the upper semiconductor package 15 may include the upper semiconductor package 15 described with reference to FIG. 4, detailed description thereof will be omitted.

Referring to FIG. 23, a method of mounting the upper semiconductor package 15 on the upper semiconductor package 10 may include a step of electrically connecting the second connection terminal 203 of the upper semiconductor package 15 to the upper redistribution layer 105 of the lower semiconductor package 10. For example, the second connection terminal 203 may be electrically connected to the upper redistribution pattern 105a of the upper redistribution layer 105.

In an exemplary embodiment of the present inventive concept, a step of mounting the upper semiconductor package 15 on the lower semiconductor package 10 may be performed in a state in which the first support substrate 700 is bonded to the lower surface of the lower redistribution layer 100. The first support substrate 700 may function to prevent damage of the lower semiconductor package 10 due to an external impact, in a step of mounting of the upper semiconductor package 10.

Referring to FIG. 24, a method of mounting the upper semiconductor package 15 on the lower semiconductor package 10 may include a step of forming the third molding member 204 and the heat sink 205. In an exemplary embodiment of the present inventive concept, the step of forming the third molding member 204 may include forming the third molding member 204 on the upper redistribution layer 105 to cover a side surface of the second molding member 202.

In an exemplary embodiment of the present inventive concept, the third molding member 204 may cover both side and a bottom surface of the second molding member 202. However, the present inventive concept is not limited thereto, and the third molding member 204 may cover only the side surface of the second molding member 202 by an etching process.

In an exemplary embodiment of the present inventive concept, step of forming the heat sink 205 may include attaching the heat sink (205) on the third molding member 204 by using an adhesive film.

In an exemplary embodiment of the present inventive concept, step of mounting the upper semiconductor package 15 on the lower semiconductor package 10 may include a step of separating the first support substrate 700 from the lower redistribution layer 100. The step of separating the first support substrate 700 from the lower redistribution layer 100 may be performed after forming the third molding member 204 and the heat sink 205.

While the present inventive concept has been particularly shown and described with reference to exemplary embodiments thereof, it will be understood that various changes in form and details may be made therein without departing from the spirit and scope of the present inventive concept as set forth in the following claims.

What is claimed is:

1. A method of manufacturing a semiconductor package, comprising:
forming a lower redistribution layer;
forming a conductive post on the lower redistribution layer;
mounting a semiconductor chip on the lower redistribution layer,
forming a molding member on the lower redistribution layer, wherein an upper surface of the molding member is at a level lower than an upper surface of the conductive post;
forming an insulating layer on the molding member, wherein an upper surface of the insulating layer is at a level higher than the upper surface of the conductive post;
etching the insulating layer to expose the upper surface of the conductive post; and
forming an upper redistribution layer on the insulating layer, wherein the upper redistribution layer is electrically connected to the conductive post.

2. The method of manufacturing the semiconductor package of claim 1, further comprising mounting an external connection terminal on the lower redistribution layer, wherein
the forming of the upper redistribution layer comprises:
coating a photoresist layer on the insulating layer;
aligning an alignment key formed on a photomask with the upper surface of the conductive post;
patterning the photoresist layer by using the photomask; and
forming an upper redistribution pattern and an upper insulating pattern.

3. The method of manufacturing the semiconductor package of claim 2, wherein the forming of the upper redistribution pattern and the upper insulating pattern comprises:
forming a plurality of upper redistribution patterns and a plurality of upper insulating patterns,
wherein a lowermost portion of the upper redistribution patterns is formed at a level higher than the upper surface of the insulating layer, and
wherein a lower surface of the lowermost portion of the upper redistribution patterns is formed at the same level as the upper surface of the insulating layer and the upper surface of the conductive post.

4. The method of manufacturing the semiconductor package of claim 1, wherein
the forming of the molding member on the lower redistribution layer comprises:
forming a first molding member on the lower redistribution layer, the first molding member including a first filler,
wherein the first filler is included in the first molding member at a weight ratio of about 30 wt % to about 90 wt %.

5. The method of manufacturing the semiconductor package of claim 4, wherein
the forming of the insulating layer on the molding member comprises:
forming a first insulating layer on the molding member, the first insulating layer including a second filler,
wherein a weight ratio of the second filler in the first insulating layer is less than the weight ratio of the first filler in the first molding member.

6. The method of manufacturing the semiconductor package of claim 5, wherein
the second filler is included in the first insulating layer at a weight ratio of about 0.1 wt % to about 30 wt %.

7. The method of manufacturing the semiconductor package of claim 1, wherein
the forming of the insulating layer on the molding member comprises:
forming a first insulating layer on the molding member, the first insulating layer comprising polyimide, epoxy, synthetic rubber, and/or benzocyclobutene (BCB).

8. The method of manufacturing the semiconductor package of claim 1, wherein
the forming of the conductive post comprises:
forming the conductive post having a cylindrical or polygonal shape on the lower redistribution layer.

9. A method of manufacturing a lower semiconductor package of a package-on-package type semiconductor package comprising:
forming a lower redistribution layer;
forming a conductive post on the lower redistribution layer;
mounting a first semiconductor chip on the lower redistribution layer;
forming a molding member on the lower redistribution layer;
forming an insulating layer on the molding member;
etching the insulating layer to expose an upper surface of the conductive post;
forming an upper redistribution layer on the insulating layer, wherein the upper redistribution layer is electrically connected to the conductive post; and
mounting an external connection terminal on the lower redistribution layer,
wherein the package-on-package type semiconductor package includes an upper semiconductor package disposed on the lower semiconductor package.

10. The method of manufacturing the lower semiconductor package of claim 9, wherein
the forming of a molding member on the lower redistribution layer comprises:
forming the molding member on the lower redistribution layer, wherein an upper surface of the molding member is at a level lower than an upper surface of the conductive post,
wherein the forming of the insulating layer on the molding member comprises:
forming the insulating layer on the molding member, wherein an upper surface of the insulating layer is at a level higher than the upper surface of the conductive post.

11. The method of manufacturing the lower semiconductor package of claim 9, wherein
the mounting of the first semiconductor chip on the lower redistribution layer comprises:
attaching an adhesive layer on the lower redistribution layer; and
electrically connecting a second connection terminal electrically connected to the first semiconductor chip to the lower redistribution layer.

12. The method of manufacturing the lower semiconductor package of claim 9, wherein
the forming of the upper redistribution layer comprises:
coating a photoresist layer on the insulating layer;
aligning an alignment key formed on a photomask with the upper surface of the conductive post;
patterning the photoresist layer by using the photomask; and
forming an upper redistribution pattern and an upper insulating pattern.

13. The method of manufacturing the lower semiconductor package of claim 12, wherein
the forming of the upper redistribution pattern and the upper insulating pattern comprises:
forming a plurality of upper redistribution patterns and a plurality of upper insulating patterns,
wherein a lowermost portion of the upper redistribution pattern is formed flat and is not bent toward the conductive post, and
wherein a portion of the lowermost portion of the upper redistribution pattern is formed to contact the upper surface of the conductive post.

14. The method of manufacturing the lower semiconductor package of claim 9, wherein
the forming of the molding member on the lower redistribution layer comprises:
forming a first molding member on the lower redistribution layer, the first molding member including a first filler, and
wherein the first filler is included in the first molding member at a weight ratio of about 30 wt % to about 90 wt %.

15. The method of manufacturing the lower semiconductor package of claim 14, wherein
the forming of the insulating layer on the molding member comprises:
forming a first insulating layer without a filler on the first molding member.

16. A method of manufacturing a semiconductor package, comprising:
forming a lower redistribution layer on a support substrate;
forming a conductive post on the lower redistribution layer;
mounting a semiconductor chip on the lower redistribution layer;
forming a molding member on the lower redistribution layer, wherein an upper surface of the molding member is at a level lower than an upper surface of the conductive post;
forming an insulating layer on the molding member, wherein an upper surface of the insulating layer is at a level higher than the upper surface of the conductive post;
etching the insulating layer such that a level of the upper surface of the insulating layer is the same as a level of the upper surface of the conductive post;
forming an upper redistribution layer electrically connected to the conductive post on the insulating layer;
separating the support substrate from the lower redistribution layer; and
mounting an external connection terminal on the lower redistribution layer.

17. The method of manufacturing the semiconductor package of claim 16, wherein the forming of the conductive post comprises:
forming the conductive post having a cylindrical or polygonal shape on the lower redistribution layer,
wherein the forming of the upper redistribution layer comprises:
coating a photoresist layer on the insulating layer;
aligning an alignment key formed on a photomask with the upper surface of the conductive post;
patterning the photoresist layer by using the photomask; and
forming an upper redistribution pattern and an upper insulating pattern.

18. The method of manufacturing the semiconductor package of claim 17, wherein
the forming of the upper redistribution pattern and the upper insulating pattern comprises:
forming a plurality of upper redistribution patterns and a plurality of upper insulating patterns,
wherein a lowermost portion of the upper redistribution pattern is formed extending in a direction parallel to a direction in which the upper surface of the insulating layer extends,
wherein the lowermost portion of the upper redistribution pattern is formed flat and is not bent toward the conductive post, and
wherein a portion of the lowermost portion of the upper redistribution pattern is formed to contact the upper surface of the conductive post.

19. The method of manufacturing the semiconductor package of claim 17, wherein
the forming of the upper redistribution pattern and the upper insulating pattern comprises:
forming a plurality of upper redistribution patterns and a plurality of upper insulating patterns,
wherein a lowermost portion of the upper redistribution patterns is formed at a level higher than an upper surface of the insulating layer,
the upper surface of the lowermost part of the upper redistribution pattern does not comprise a step, and
a lower surface of the lowermost portion of the upper redistribution patterns is formed at the same level as the upper surface of the insulating layer and the upper surface of the conductive post.

20. The method of manufacturing the semiconductor package of claim 16, wherein
the forming of the molding member on the lower redistribution layer comprises:
forming a first molding member on the lower redistribution layer, the first molding member including a first filler, and
wherein the forming of the insulating layer on the molding member comprises:
forming a first insulating layer on the molding member, the first insulating layer including a second filler,
wherein the first filler is included in the first molding member at a weight ratio of about 30 wt % to about 90 wt %, and
wherein the second filler is included in the first insulating layer at a weight ratio of about 0.1 wt % to about 30 wt %.
